(19) United States
(12) Patent Application Publication
(10) Pub. No.: US 2013/0120014 A1
(43) Pub. Date: May 16, 2013

(54) TEST CARRIER

(71) Applicants: Kiyoto NAKAMURA, Miyagi (JP); Takashi FUJISAKI, Gunma (JP)

(72) Inventors: Kiyoto NAKAMURA, Miyagi (JP); Takashi FUJISAKI, Gunma (JP)

(21) Appl. No.: 13/677,355

(22) Filed: Nov. 15, 2012

(30) Foreign Application Priority Data
Nov. 16, 2011 (JP) 2011-250524

(51) Int. Cl. G01R 1/04

(52) U.S. Cl. CPC G01R 1/0408
USPC 324/756.02

(57) ABSTRACT

A test carrier which can suppress the occurrence of contact defects and secure positional precision of the terminals is provided.

The test carrier 10 comprises: a base film 40 which has bumps 43 which contact the electrode pads 91 of the die 90; a cover film 70 which is laid over the base film 40 and which covers the die 90; and a spacer 45 which is interposed between the base film 40 and the cover film 70 and which is arranged around the die 90.

### TECHNICAL FIELD

The present invention relates to a test carrier to which a die chip is temporarily mounted for testing an integrated circuit or other electronic circuit which is formed in the die chip.

The present application claims priority based on Japanese Patent Application No. 2011-250524 of a Japanese patent application which was filed on Nov. 16, 2011. The content which was described in that application is incorporated into the present application by reference and forms part of the description of the present application.

### BACKGROUND ART

Known in the art is a test carrier which comprises a contact sheet having a film made of a polyimide on which contact pads and interconnect patterns are formed. The contact pads correspond to electrode patterns of a chip under test, and the interconnect patterns are connected to the contact pads for contact with an external test apparatus (for example, see PLT 1).

### CITATIONS LIST

### Patent Literature

PLT 1: Japanese Patent Publication No. 7-2630504 A1

### SUMMARY OF INVENTION

### Technical Problem

In the above test carrier, if the film of the contact sheet is too thick, since the film is high in rigidity, the film ends up riding over the edge of the chip whereby there are the problems that the electrode patterns which are positioned near the edge and the contact pads are not electrically connected and contact defects occur.

On the other hand, if the film of the contact sheet is too thin, the problem that elongation of the base film itself or waviness of the film due to stress at the time of forming the interconnects causes a drop in the positional precision of the contact pads.

The technical problem of the present invention is to provide a test carrier which can suppress the occurrence of contact defects and secure positional precision of the terminals.

### Solution to Problem

[1] A test carrier according to the present invention comprises: a film-shaped first member which has terminals which contact electrodes of an electronic device; a second member which is laid over the first member and which covers the electronic device; and a spacer which is interposed between the first member and the second member and is arranged around the electronic device.

[2] In the above invention, the thickness of the spacer may be substantially the same as the thickness of the electronic device.

[3] In the above invention, the spacer may be arranged so as to be adjacent to a part of a contour of the electronic device which is positioned near the electrode in a plan view.

[4] In the above invention, the spacer may have a frame shape which surrounds the contour of the electronic device over an entire circumference of the contour of the electronic device in a plan view.

[5] In the above invention, the spacer may be arranged so as to be adjacent to a pair of sides among a contour of the electronic device in a plan view, and the pair of sides may mutually face.

[6] In the above invention, the electronic device may be a die which is diced from a semiconductor wafer.

[7] In the above invention, the test carrier may comprise a holding space which is formed between the first member and the second member and holds the electronic device, and the spacer may be held in the holding space.

[8] In the above invention, the holding space may be reduced in pressure compared with the outside air.

### ADVANTAGEOUS EFFECTS OF INVENTION

In the present invention, a spacer is interposed between the first member and the second member and is arranged around the electronic device, so even if not making the first member thin, the terminals of the first member can be prevented from rising up from the electrodes of the electronic device, the occurrence of contact defects can be suppressed and the positional precision of the terminals can be secured.

### BRIEF DESCRIPTION OF DRAWINGS

FIG. 1 is a flow chart which shows a part of a process of production of a device in an embodiment of the present invention.

FIG. 2 is a disassembled perspective view of a test carrier in an embodiment of the present invention.

FIG. 3 is a cross-sectional view of a test carrier in an embodiment of the present invention.

FIG. 4 is a disassembled cross-sectional view of a test carrier in an embodiment of the present invention.

FIG. 5 is an enlarged view of a part V of FIG. 4.

FIG. 6 is a disassembled cross-sectional view which shows a first modification of a test carrier in an embodiment of the present invention.

FIG. 7 is a disassembled cross-sectional view which shows a second modification of a test carrier in an embodiment of the present invention.

FIG. 8 is a bottom view which shows the positional relationship between a spacer and a die in an embodiment of the present invention.

FIG. 9 is a view which shows a modification of a spacer of an embodiment of the present invention.

FIG. 10(a) is an enlarged view of a part X of FIG. 3, while FIG. 10(b) is an enlarged view of a conventional test carrier.

### DESCRIPTION OF EMBODIMENTS

Below, an embodiment of the present invention will be explained based on the drawings.

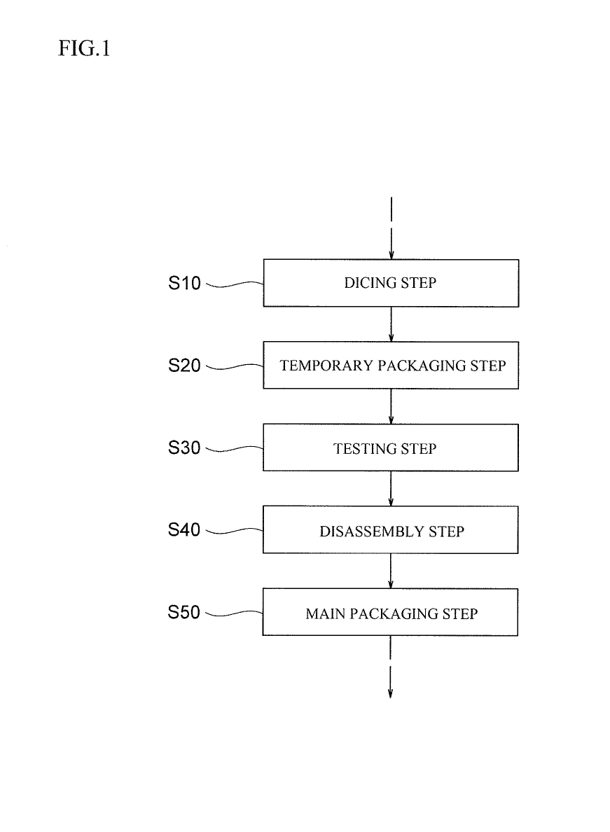

FIG. 1 is a flow chart which shows a part of a process of production of a device in the present embodiment.

In the present embodiment, after a semiconductor wafer is diced (after FIG. 1, step S10) and before final packaging (before step S50), the electronic circuits which are built into the die 90 are tested (steps S20 to S40).

In the present embodiment, first, a carrier assembly device (not shown) is used to temporarily mount a die 90 to a test carrier 10 (step S20). Next, through this test carrier 10, the die 90 and the test system (not shown) are electrically connected so as to test the electronic circuits which are built into the die 90 (step S30). Further, after this test ends, the die 90 is taken out from the test carrier 10 (step S40), then this die 90 is packaged by main packaging to thereby complete the device as a final product (step S50).

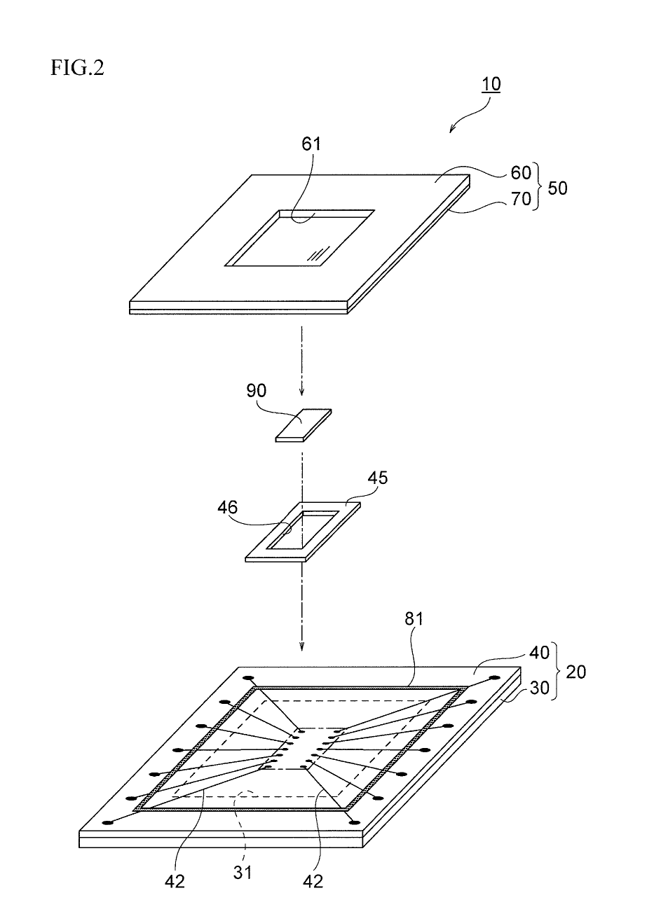

Below, the configuration of the test carrier 10 to which the die 90 is temporarily mounted (provisionally packaged) in the present embodiment will be explained while referring to FIG. 2 to FIG. 10.

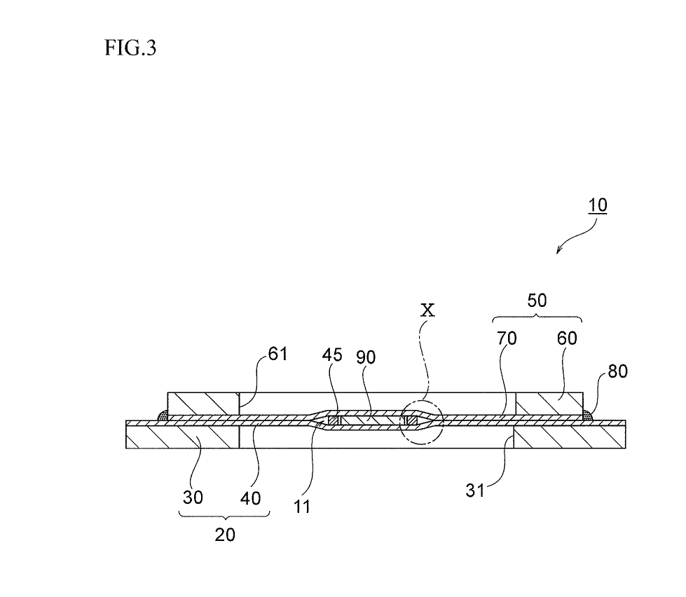

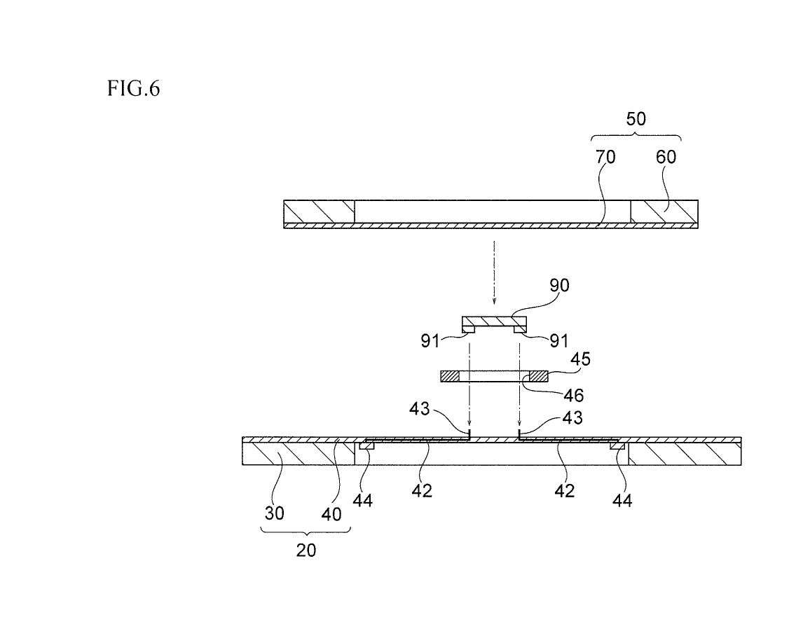

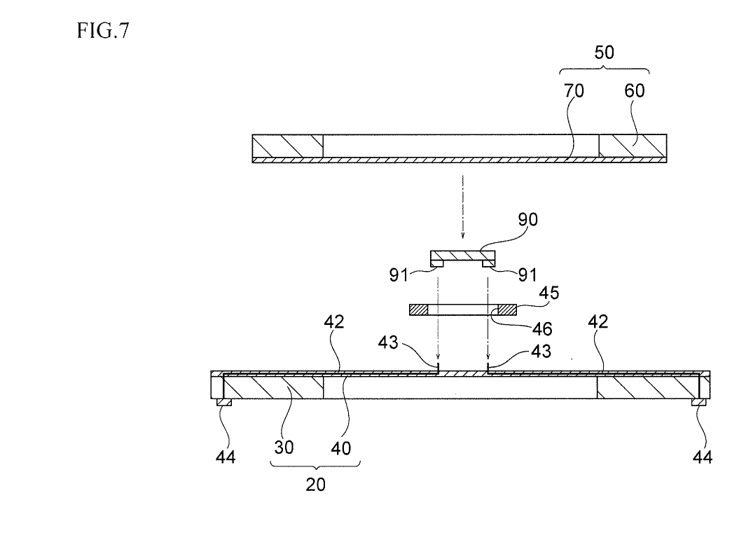

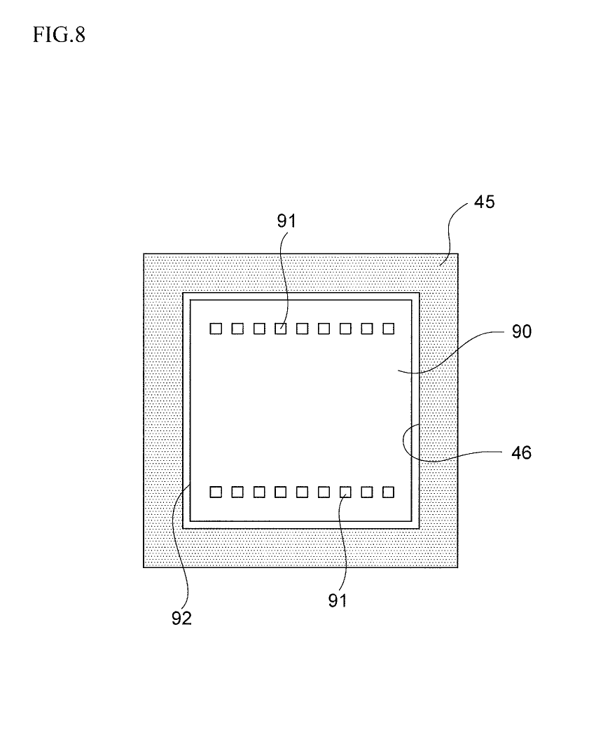

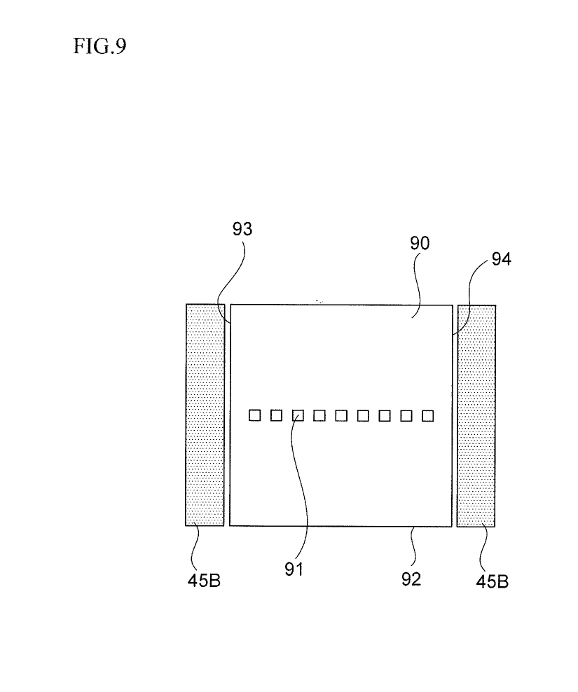

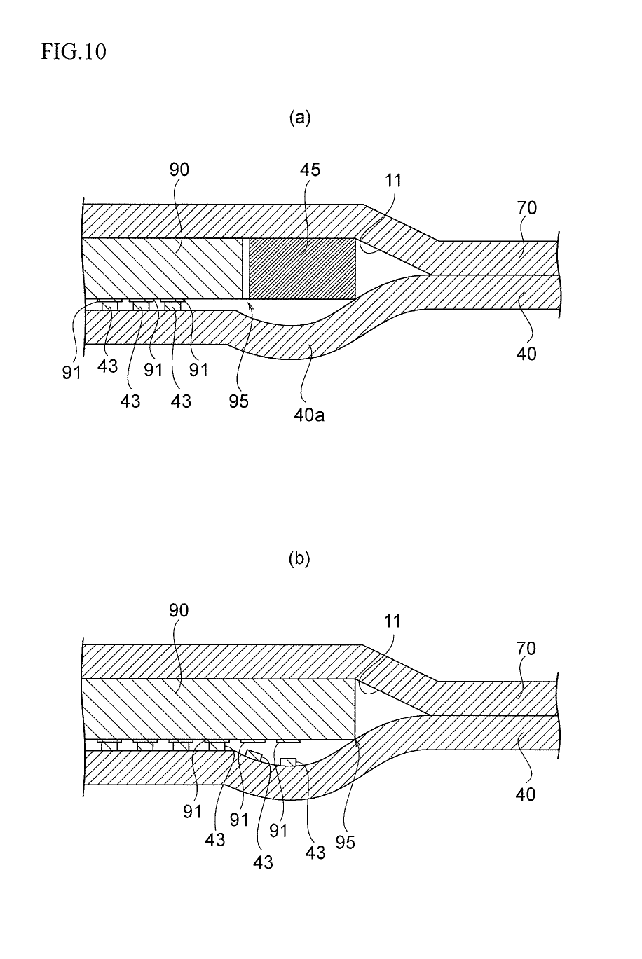

FIG. 2 to FIG. 5 are views which show a test carrier in which a die 90 is temporarily mounted, FIG. 6 and FIG. 7 are views which show modifications of the test carrier, FIG. 8 is a view which shows the positional relationship between a spacer 45 and a die 90, FIG. 9 is a view which shows a modification of a spacer, FIG. 10(a) is an enlarged view of a part X of FIG. 3, and FIG. 10(b) is an enlarged view of a conventional test carrier.

The test carrier 10 in the present embodiment, as shown in FIG. 2 to FIG. 4, comprises: a base member 20 on which a die 90 is carried; a spacer 45 which is arranged around the die 90; and a cover member 50 which is laid over the base member 20 and covers the die 90 and the spacer 45. This test carrier 10 sandwiches the die 90 between the base member 20 and the cover member 50 in a state reduced in pressure from atmospheric pressure to thereby hold the die 90.

The base member 20 comprises a base frame 30 and a base film 40. The base film 40 in the present embodiment is equivalent to one example of the first member in the present invention.

The base frame 30 is a rigid board which has a high rigidity (at least a rigidity higher than the base film 40 or the cover film 70) and is formed with an opening 31 at the center. As the material which forms this base frame 30, for example, a polyamide imide resin, ceramic, glass, etc. may be illustrated.

On the other hand, the base film 40 is a film which has flexibility and is attached to the entire surface of the base frame 30, including the center opening 31, through a binder (not shown). In this way, in the present embodiment, since the base film 40 which has flexibility is attached to the base frame 30 which has a high rigidity, the handling ability of the base member 20 is improved.

Note that, it is also possible to omit the base frame 30 and configure the base member 20 by only the base film 40. Alternatively, it is also possible to omit the base film 40 and use a rigid printed circuit board as the base member 20, the rigid printed circuit board is the base frame on which the interconnect patterns 42 is formed and which does not have the opening 31.

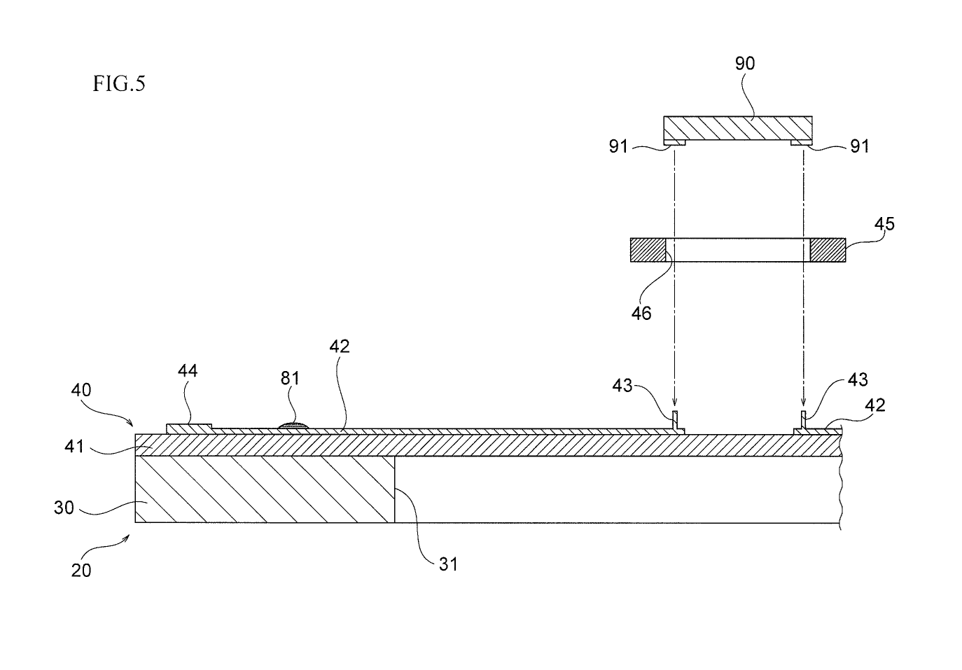

As shown in FIG. 5, this base film 40 has a film body 41 and interconnect patterns 42 which are formed on the surface of the film body 41. The film body 41, for example, comprises a polyimide film etc. Further, the interconnect patterns 42 are, for example, formed by etching copper film which is laminated on the film body 41.

Note that, the film body 41 may be laminated with a cover layer which for example comprises a polyimide film so as to protect the interconnect patterns 42 or a so-called multilayer flexible printed circuit board may be used as the base film 40. Further, part of the interconnect patterns 42 may be formed on the surface of the base film 40 by ink jet printing in real time. Alternatively, all of the interconnect patterns 42 may be formed by ink jet printing.

As shown in FIG. 5, a bump 43 which electrically contacts an electrode pad 91 of the die 90 is provided at one end of each interconnect pattern 42. This bump 43 is, for example, composed of copper (Cu), nickel (Ni), etc. and, for example, is formed by the semiadditive method on the end of the interconnect pattern 42. Such bumps 43 are arranged so as to correspond to electrode pads 91 of the die 90. The die 90 in the present embodiment is equivalent to one example of an electronic device in the present invention, the electrode pad 91 in the present embodiment is equivalent to one example of the electrode in the present invention, and the bump 43 in the present embodiment is equivalent to one example of the terminal in the present invention.

On the other hand, an external terminal 44 is provided at the other end of each interconnect pattern 42. At the time of a test of the electronic circuits which are built into the die 90 (FIG. 1, step S30), such external terminals 44 are electrically contacted by contactors of the test system (not shown) whereby the die 90 is electrically connected through the test carrier 10 to the test system.

Note that, the positions of the external terminals 44 are not particularly limited to the above positions. For example, as shown in FIG. 6, the external terminals 44 may also be formed on the bottom surface of the base film 40. Alternatively, as shown in FIG. 7, the external terminals 44 may be formed on the bottom surface of the base frame 30. In the example which is shown in FIG. 7, the base frame 30 is formed with through holes and interconnect patterns so as to electrically connect the interconnect patterns 42 and the external terminals 44.

Further, while not particularly shown, in addition to the base film 40, the cover film 70 may also be formed with the interconnect patterns 42 or external terminals 44, and the cover frame 60 may be formed with the external terminals 44.

On the above explained base film 40, the object under test, that is, the die 90, is placed. In the present embodiment, in addition to the die 90, a spacer 45 is also placed on the base film 40.

This spacer 45, as shown in FIG. 8, has a rectangular frame shape and has an inside hole 46 which is slightly larger than the die 90. The spacer 45 holds the die 90 in this inside hole 46 and, in the plan view, can surround the contour (outer edge) 92 of the die 90 across the entire circumference. Note that, the entire circumference of the contour 92 of this die 90 in the present embodiment is equivalent to one example of the “a part of a contour of the electronic device which is positioned near the electrode” in the present invention.

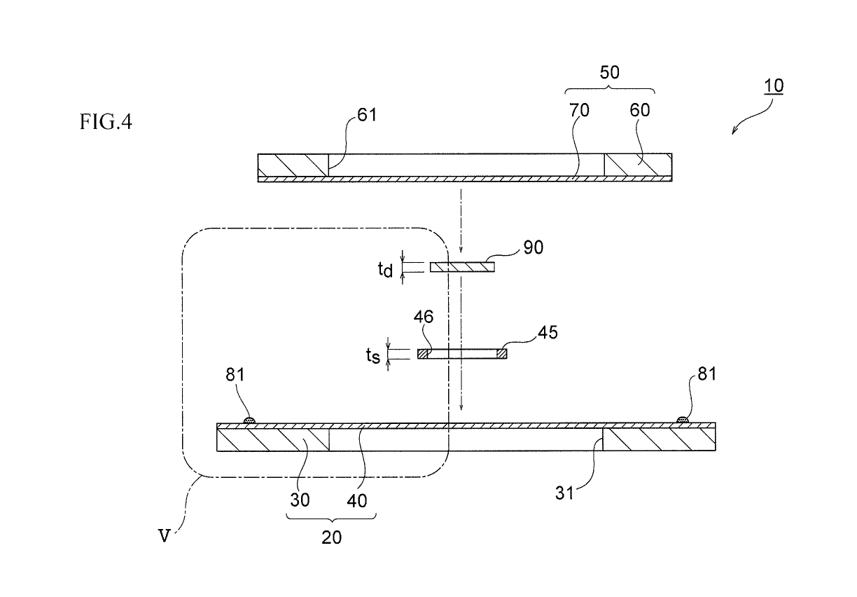

This spacer 45 is, for example, composed of a polytetrafluoroethylene (PTFE) or other resin material, silicon (Si), ceramic, glass, etc. As shown in FIG. 4, this spacer 45 has a thickness tₛ which is substantially the same thickness as the thickness t_{d} of the die 90 (tₛ=t_{d}). Note that, so long as the bumps 43 of the base film 40 do not rise up from the electrode pads 91 of the die 90, the thickness tₛ of the spacer 45 may also be made somewhat thicker or thinner than the thickness t_{d} of the die 90.

Note that, for example, as shown in FIG. 9, when a line of electrode pads 91 is provided only at the substantial center of the die 90, two spacers 45B which sandwich the die 90 between them may also be placed on the base film 40. Specifically, as shown in the figure, in the plan view, a pair of spacers 45B may also be arranged so as to be adjacent to a pair of sides 93, 94 which are among the contour 92 of the die 90 and which are positioned near the electrode pads 91. Note that, this pair of sides 93, 94 in the present embodiment are equivalent to one example of the “a part of a contour of the electronic device which is positioned near the electrode” in the present invention.

Returning to FIG. 2 to FIG. 4, the cover member 50 comprises a cover frame 60 and a cover film 70. The cover film 70 in the present embodiment is equivalent to one example of the second member in the present invention.

The cover frame 60 is a rigid board which has a high rigidity (at least a rigidity which is higher than the base film 40 or the cover film 70) and which is formed with an opening 61 at its center. In the present embodiment, this cover frame 60, like the above-mentioned base frame 30, is composed of a polyimide resin, ceramic, glass etc.

On the other hand, the cover film 70 is a film which has flexibility and, for example, in the same way as the film body 41 of the above-mentioned base film 40, comprises a polyimide film etc. This cover film 70 is adhered to the entire surface of the cover frame 60, including the center opening 61, by a binder (not shown). In the present embodiment, a flexible cover film 70 is adhered to the high rigidity cover frame 60, so an improvement in the handling ability of the cover member 50 is achieved.

Note that, the cover member 50 may also comprise only the cover film 70. Alternatively, when the base member 20 has the base film 40, the cover member 50 may comprise only the rigid board not formed with the opening 61.

The above explained test carrier 10 is assembled as explained below.

First, in the state where the electrode pads 91 are aligned with the bumps 43, the die 90 is placed on the base film 40 of the base member 20, next, while the inside hole 46 holds the die 90, the spacer 45 is placed on the base film 40.

Next, in an environment which is reduced in pressure compared with atmospheric pressure, the cover member 50 is laid over the base member 20 to sandwich the die 90 and spacer 45 between the base member 20 and the cover member 50. At this time, the base film 40 and the cover film 70 are made to directly contact by laying the cover member 50 over the base member 20.

Incidentally, when the die 90 is relatively thick, while not particularly shown, the base frame 30 and the cover frame 60 may be made to directly contact by laying the cover member 50 over the base member 20.

Next, in the state with the die 90 sandwiched between the base member 20 and the cover member 50, the test carrier 10 is returned to an atmospheric pressure environment whereby the die 90 is held inside the holding space 11 (see FIG. 3) which is formed between the base member 20 and the cover member 50.

Here, as shown in FIG. 10(b), when the spacer 45 is not provided around the die 90, if the base film 40 is too thick, the base film 40 rides over the edge 95 of the die 90, part of the bumps 43 end up rising from the electrode pads 91, the electrode pads 91 which are positioned near the edge 95 of the die 90 do not electrically contact the bumps 43, and therefore contact defects occur.

On the other hand, while not particularly shown, if the base film is too thin in thickness, elongation of the base film itself or waviness of the base film due to stress at the time of forming the interconnects cause a drop in the positional precision of the bumps.

As opposed to this, in the present embodiment, as shown in FIG. 10(a), even if the base film 40 has a predetermined rigidity, the spacer 45 enables the electrode pads 91 which are positioned near the edge 95 of the die 90 to be separated from the raised up part 40a of the base film 40 and therefore the raised up state of the bumps 43 can be suppressed and occurrence of contact defects can be suppressed.

Incidentally, the electrode pads 91 of the die 90 and the bumps 43 of the base film 40 are not fastened by solder etc. In the present embodiment, the holding space 11 becomes a negative pressure compared with atmospheric pressure, so the die 90 is pushed by the base film 40 and the cover film 70, and the electrode pads 91 of the die 90 and the bumps 43 of the base film 40 contact each other.

Note that, as shown in FIG. 3, the base member 20 and the cover member 50 may also be fastened together by the bonded part 80 so as to prevent positional deviation and improve the air-tightness. As the binder 81 which forms this bonded part 80, for example, a UV curing type binder may be illustrated.

This binder 81, as shown in FIG. 2, FIG. 4, and FIG. 5, is applied on the base member 20 at positions corresponding to the outer circumference of the cover member 50. By placing the cover member 50 on the base member 20, then firing UV rays to cure the binder 81, the bonded part 80 is formed.

The above assembled test carrier 10 is transported to a not particularly shown test system where, in step S30 of FIG. 1, the contactors of the test system electrically contact the external terminals 44 of the test carrier 10, the test system and the electronic circuits of the die 90 are electrically connected through the test carrier 10, and the electronic circuits are tested.

Note that, when bonding the base member 20 and the cover member 50 by the bonded part 80, then pushing the test carrier 10 from the outside at the time of the test so as to make the electrode pads 91 of the die 90 and the bumps 43 contact, the holding space 11 need not be reduced in pressure.

In the above way, in the present embodiment, the spacer 45 is interposed between the base film 40 and the cover film 70 and is arranged around the die 90, so even if not making the base film 40 thinner, the bumps 43 of the base film 40 can be prevented from rising up, the occurrence of contact defects can be suppressed, and the positional precision of the bumps 43 can be secured.

Note that, the above explained embodiment was described to facilitate understanding of the present invention and was not described for limiting the present invention. Therefore, the elements which were disclosed in the embodiment include all design changes and equivalents falling under the technical scope of the present invention.

### REFERENCE SIGNS LIST

10 . . . test carrier
11 . . . holding space
20 . . . base member
30 . . . base frame
31 . . . center opening
40 . . . base film
40a . . . raised up part
41 . . . film body
42 . . . interconnect pattern
43 . . . bump
44 . . . external terminal
45 . . . spacer
46 . . . inside hole
50 . . . cover member
60 . . . cover frame
61 . . . center opening
70 . . . cover film
80 . . . bonded part
81 . . . binder
90 . . . die
91 . . . electrode pad
92 . . . contour
93, 94 . . . side
95 . . . edge

1. A test carrier comprising:
a film-shaped first member which has terminals which contact electrodes of an electronic device;
a second member which is laid over the first member and which covers the electronic device; and
a spacer which is interposed between the first member and the second member and is arranged around the electronic device.

2. The test carrier as set forth in claim 1, wherein the thickness of the spacer is substantially the same as the thickness of the electronic device.

3. The test carrier as set forth in claim 1, wherein the spacer is arranged so as to be adjacent to a part of a contour of the electronic device which is positioned near the electrode in a plan view.

4. The test carrier as set forth in claim 1, wherein the spacer has a frame shape which surrounds the contour of the electronic device over an entire circumference of the contour of the electronic device in a plan view.

5. The test carrier as set forth in claim 1, wherein the spacer is arranged so as to be adjacent to a pair of sides among a contour of the electronic device in a plan view, and the pair of sides mutually face.

6. The test carrier as set forth in of claim 1, wherein the electronic device is a die which is diced from a semiconductor wafer.

7. The test carrier as set forth in claim 1, comprising a holding space which is formed between the first member and the second member and holds the electronic device, wherein
the spacer is held in the holding space.

8. The test carrier as set forth in claim 7, wherein the holding space is reduced in pressure compared with the outside air.
